(19) United States
(12) Patent Application Publication
(10) Pub. No.: US 2024/0322070 A1
(43) Pub. Date: Sep. 26, 2024

(54) METHOD FOR TRANSFERRING A COMPONENT

(71) Applicant: OSRAM OPTO SEMICONDUCTORS GMBH, Regensburg (DE)

(72) Inventor: Jens Ebbecke, Helchenbach (DE)

(21) Appl. No.: 18/580,122

(22) PCT Filed: Jul. 20, 2022
(86) PCT No.: PCT/EP2022/070415

§ 371 Date: Jan. 17, 2024

(30) Foreign Application Priority Data
Jul. 22, 2021 (DE) 10 2021 118 957.8

(51) Int. Cl. H01L 33/00; H01L 33/40

(52) U.S. Cl. CPC H01L 33/0093; H01L 33/40; H01L 2933/0016

(57) ABSTRACT

In an embodiment a method includes providing at least one component attached to a first carrier via a support holder, positioning a light-conducting lifting element with a light emitting surface opposite the transfer area, generating a first laser light pulse through the light emitting surface, locally melting a transfer material between the light emitting surface and the transfer area caused by the first laser light pulse, connecting the light emitting surface to the transfer area with the melted transfer material, lifting the at least one component so as to separate the component from the support holder, positioning the at least one component above a deposition area, generating a second laser light pulse through the light emitting surface so that the transfer material is melted again and moving the lifting element away from the transfer area before the transfer material solidifies and so that the component remains on the deposition area.

### CROSS-REFERENCE TO RELATED APPLICATIONS

This patent application is a national phase filing under section 371 of PCT/EP2022/070415, filed Jul. 20, 2022, which claims the priority of German patent application 10 2021 118 957.8, filed Jul. 22, 2021, each of which is incorporated herein by reference in its entirety.

### BACKGROUND

Various methods are known for the transfer of electronic components and devices from a growth carrier to an auxiliary carrier or a target substrate or printed circuit board. However, the ever smaller components, especially small optoelectronic components, make error-free transfer more difficult due to various effects. For example, it is difficult to control the individual adhesive forces of small components, meaning that not all components may be fully transferred during a transfer. It is therefore possible that when the components are deposited, they may still adhere to a conventional stamp pad or may not be placed correctly.

For example, optoelectronic components, so-called light emitting diodes or u light emitting diodes with a very small edge length can be transferred using a type of rubber stamp. However, different levels of attraction forces must be taken into account here, meaning that the transfer is sometimes faulty or incomplete. It is particularly critical that the attractive forces between the stamp and the individual components must be greater than the adhesive force of the components on a carrier and should in turn be less than the adhesive force between the components and the respective deposition area.

There is therefore still a need for a process for transferring electronic components that ensures the safest possible handling and correct transfer.

### SUMMARY

Embodiments provide a method for transferring a component, in particular an optoelectronic component.

At least one component is provided, which is attached to a first carrier via a support holder. The component also comprises a transfer area, which is arranged on a side of the component facing away from the first carrier. In this context, the first carrier can be the growth substrate, an auxiliary carrier or the like, to which the component is held via a support holder that is still present.

In a second step, a light-conducting lifting element is provided, which has a light emitting surface. This is positioned opposite the transfer area of the at least one component. A first laser light pulse is then generated, which passes through the light emitting surface. The laser light pulse has an energy input that causes a local melting of a transfer material, which is arranged between the light emitting surface and the transfer area. The local melting of the transfer material connects the light emitting surface to the transfer area and thus attaches the component to the lifting element.

This intimate connection now allows the at least one component to be lifted off in a subsequent step so that it is separated from the support holder. Due to the local melting, the adhesive force exerted by the transfer material between the light emitting surface of the lifting element and the transfer area of the component is so great that the component can be separated from the support holder, for example broken off or even torn away. After lifting off, the component, which is now attached to the lifting element, is repositioned over a deposition area. This storage area can be part of an end support, but can also be a PCB, a storage surface of another component or similar.

After positioning the at least one component over the deposition area, a second laser light pulse is now generated by the light emitting surface. The energy introduced by the laser light pulse now melts the transfer material again locally. This reduces the adhesive force between the at least one component on the transfer area and the transfer material, so that the latter either falls down onto the depositing area or is now held by it. In the liquid state of the transfer material, the light-conducting lifting element can be moved away again so that the component remains on the deposition area. This last movement takes place before the transfer material solidifies again.

In contrast to conventional techniques, the method proposed here uses a stamp pad to create a very strong and intimate connection between the lifting element and the component to be transferred. On the one hand, this connection can be created by the introduced light pulse and on the other hand, it can be separated again by another light pulse so that the component remains in the target position or can be deposited there.

By using several such lifting elements, mass transfer can be accomplished in a simple manner. In addition, it is also possible to selectively apply a laser light pulse to the individual lifting elements so that a selective connection of the component to the lifting element or a selective release of such a component is possible. In this way, components can be selectively transferred or open areas can be selectively fitted with components during placement.

The process proposed here can therefore be used in particular in the manufacture of displays or display devices and the transfer of very small optoelectronic components, so-called μ-LEDs with an edge length in the range of a few μm.

In some aspects, the light-conducting lifting element is designed as a glass fiber, whereby the light pulse is emitted through the glass fiber. The light emitting surface of the glass fiber thus also forms the area to which the component is attached by means of the transfer material. By using a laser light pulse, the energy input to be introduced can be controlled so that melting only occurs locally and is limited to the transfer material. A very short laser pulse in the range of a few nanoseconds, for example in the range of 5 ns to 20 ns, generates sufficient energy for localized melting and is so short that heat conduction into the surrounding areas is avoided. This prevents damage to the component due to excessive thermal development.

A further aspect relates to the positioning of the light-conducting lifting element over or on the transfer area. In some aspects, it is provided that the light-conducting lifting element is positioned on the transfer area so that the transfer material contacts both the light emitting surface of the lifting element and the transfer area of the component. In this context, it can also be provided that a slight force is exerted on the transfer area by the lifting element during the melting process, so that the transfer material forms an intimate bond with both.

Alternatively, the light-conducting lifting element can also be positioned at a predetermined height above the transfer area. The distance between the transfer area of the component and the lifting element or the transfer material is selected in such a way that the transfer material undergoes a change in shape during the melting process so that it comes into contact with the transfer area. For example, the transfer material can change in the shape of a droplet during the melting process so that it now has a greater length and thus contacts the transfer area so that it connects it to the lifting element after re-solidification.

In some aspects, the area of local melting is smaller than an area of the light emitting surface. In other words, local melting thus occurs primarily in the area where the light pulse hits the transfer material, but the energy input is so low that areas outside the area of the light pulse do not melt or melt only slightly. In order to take particular account of this effect and to realize its advantages, a special shape of the light emitting surface of the lifting element is implemented in some aspects.

For example, the emitting area can be designed to be flat so that the transfer material on this flat surface bonds intimately with the light emitting surface. In an alternative embodiment, however, the lifting element is designed with a tapered tip, at the end of which the transfer material is applied. In this context, the light pulse can be designed in such a way that the pulse melts the transfer material completely at the lower end of the tip so that it forms a drop-shaped structure in the molten state. The component is captured in the transfer area with this droplet and, after re-solidification, the droplet-shaped transfer material connects the component to the lifting element.

In an alternative embodiment, the light emitting surface of the lifting element can also be conical or hemispherical. Further possibilities would be a tapered tip, a pyramid-shaped tapered tip or even a beveled surface. In some aspects, the surface of the light emitting surface or generally the surface of the tip of the lifting element is smaller than a surface of the transfer area.

In some embodiments, the light-conducting lifting element is positioned at a predetermined height above the transfer area and the light pulse is then generated. During the generation of the light pulse, the light-conducting lifting element is moved further towards the transfer area of the component until the liquid transfer material bonds with the transfer area. This movement can take place during the light pulse, but also a short time after the light pulse, whereby the transfer material is still liquid or semi-liquid at this point, so that contact and wetting with the transfer area and a connection can take place.

After the transfer material has solidified, the adhesive force of the transfer material on the transfer area or the adhesive force of the transfer material on the light emitting surface of the lifting element is greater than a corresponding holding force exerted on the component by the support holders. This allows the component to be separated from the support element, for example by breaking or tearing it off, without the component being detached from the lifting element.

In the previous embodiments, the transfer material is arranged on the lifting element and is melted by it by generating the light pulse. In another embodiment, however, it is also possible to apply the transfer material to the transfer area before the actual transfer process. Melting of the transfer material takes place after positioning, in particular after contact of the light emission side with the transfer material, so that the generated light pulse from the light emission side passes directly into the transfer material and causes local melting there. This design has the advantage that the transfer material can already be applied or deposited on the transfer area in various ways during the manufacturing process.

It is also useful in this respect if the transfer material is also available for further steps and subsequent process control, for example contacting the component. In these aspects, it can be useful if little or no transfer material remains on the lifting element after the component has been re-melted and deposited on the target carrier. In these aspects, the transfer area can thus also immediately form part of a contact of the component.

In other aspects, the transfer material is part of the lifting element and in some aspects should not or hardly remain on the transfer area of the component after a transfer. In some aspects, only a small portion of the transfer material remains back on the transfer area after the lifting element is moved away. This portion may be less than 20% of the original mass of the transfer material, in particular less than 10% or even less than 5% of the original mass. In some aspects, a loss of the transfer material on the lifting element should be as low as possible in order to be able to carry out several transfer processes of components without having to renew the transfer material on the lifting element.

In some aspects, the lifting elements may be positioned over a supply layer of transfer material to renew the transfer material. A high-energy light pulse is then generated to melt the transfer material below the light emitting surface and pick it up at the lifting element.

In some aspects, it is useful to generate a new light pulse after the lifting element has been moved away in order to melt the transfer material remaining on the lifting element. By re-melting, the transfer material can be planarized or brought into a desired shape on the light emitting surface. This process is useful in order to create a surface that is as uniform as possible for a new transfer process.

Various different materials can be used for the transfer material. On the one hand, materials can be used that are also required for further processing of the component after the transfer. The advantage of using such a material is that any remaining transfer material on the component does not result in heavy contamination that impairs the electrical functionality. In other aspects, the transfer material may comprise at least one material from which the transfer area of the component is also formed.

Such materials are, for example, indium, gallium, nickel, silver, gold or tin. If a transparent electrical contact is used for the component, for example ITO, it is advisable to use tin or indium as the transfer material. Gallium can also be used well, as indium and gallium are both low-melting-point metals, which means that the energy input and therefore the light pulse can be as short as possible.

In other aspects, gold or silver can be used, as these materials are particularly suitable for refining contact surfaces and creating contacts that are easy to solder.

Alternatively, a thermoplastic or silicone can also be used as a transfer material. These are characterized by particularly residue-free lifting processes, so that hardly any or only very little transfer material remains on the transfer area of the component. The strength and length of the light pulse is adjusted to the transfer material to be used and selected so that only as much transfer material melts as is necessary to overcome the adhesive force of the component on the first carrier.

Another aspect relates to a transfer arrangement which has a plurality of glass fiber lines with light emitting surfaces located at their ends. Each glass fiber line is selectively connected to a light generation arrangement which generates laser pulses of only a few nanoseconds duration. The spacing and the shape of the large number of glass fiber lines is selected so that they are particularly suitable for accommodating components. A fusible transfer material is arranged on the light emitting surface of each of the glass fiber lines. In addition, the transfer arrangement comprises a movement device with which the glass fiber cables can be moved both vertically and horizontally. According to the invention, the transfer arrangement is designed to position the light emitting surface of the glass fiber cables over respective transfer areas of a plurality of components and then either selectively or also jointly generate a plurality of laser light pulses for melting the transfer material on the light emitting surfaces of the glass fiber cables.

In some embodiments, the transfer arrangement is adapted to perform a vertical movement during the generation of the plurality of laser light pulses, thereby exerting a force on the surface of the transfer area through the fiber optic lines. The force is such that the fused-on transfer material creates a bond between the end of the fiber optic lines and the respective transfer areas of the devices without damaging or removing the devices from the support holders.

In some embodiments, a laser interferometer or another interferometer is provided for vertical alignment, which controls the vertical movement of the fiber optic cables via a coupling. In this way, particularly precise positioning in the vertical direction above the components is possible. Alternatively, control can also take place via a capacitive measurement between the component and the fiber optic cable.

The light generation arrangement is designed to generate laser light pulses in the range of a few nanoseconds, for example in the range of 5-30 ns.

### BRIEF DESCRIPTION OF THE DRAWINGS

Further aspects and embodiments according to the proposed principle will become apparent with reference to the various embodiments and examples described in detail in connection with the accompanying drawings.

FIG. 1 shows the first steps a) and b) of a process for transferring components according to the proposed principle;

FIG. 2 shows in its sub FIGS. c) to e) further aspects of the process for transferring components according to the proposed principle;

FIG. 3 shows a cross-section of various configurations of the tips of a fiber optic cable, which can be used to transfer components according to the proposed principle;

FIG. 4 shows in sub FIGS. a) to c) a further example of a method for transferring components according to the proposed principle;

FIG. 5 with its partial views a) to c) is a detailed illustration of a tear-off process of transfer material; and

FIG. 6 is an example of a transfer arrangement according to the proposed principle.

### DETAILED DESCRIPTION OF ILLUSTRATIVE EMBODIMENTS

The following embodiments and examples show various aspects and their combinations according to the proposed principle. The embodiments and examples are not always to scale. Likewise, various elements may be shown enlarged or reduced in size in order to emphasize individual aspects. It is understood that the individual aspects and features of the embodiments and examples shown in the FIGS. can be readily combined with each other without affecting the principle of the invention. Some aspects have a regular structure or shape. It should be noted that slight deviations from the ideal shape may occur in practice without, however, contradicting the inventive concept.

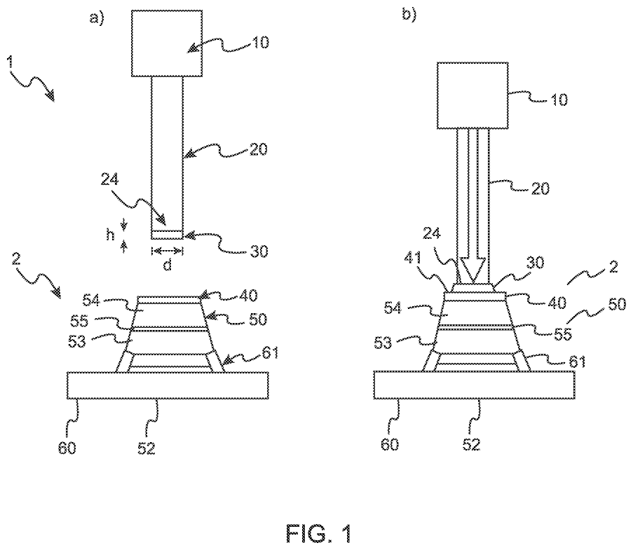

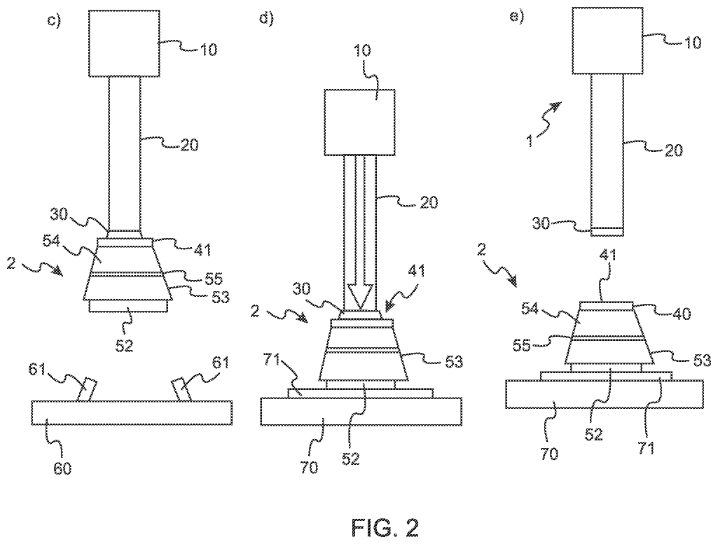

FIGS. 1 and 2 show in their respective sub-FIGS. a) and b) as well as c) to e) different process steps of a transfer of an electronic component according to the proposed principle.

In this example, the component 2 is designed as an optoelectronic component, a so-called u light emitting diode. However, it is also possible without difficulty to transfer other components, for example silicon-based components or other optoelectronic components, using this process. In this respect, the optoelectronic component shown here is to be understood merely as an example.

The component comprises a semiconductor layer stack 50 consisting of various semiconductor layers 53, 54 and 55 and is designed as a vertical light emitting diode with a rear connection contact 52 and a top connection contact 40. The top-side connection contact 40 also forms the transfer area 41, with which the component is later transferred to an end carrier.

In the embodiment example presented, the component 2 is connected to a carrier substrate 60 via a support holder 61. As shown, the contact 52 is spaced from the surface of the substrate carrier 60 on the underside, so that the component 2 rests only on the support holder 61. In the embodiment shown here, two support holders 61 are provided. These support holders on the edges of the component are also suitable for supporting other components arranged next to it and not shown here.

However, it is also possible to provide only a central or offset support holder to which the component is attached. In some embodiments, such a support holder can also be dispensed with if an adhesive force between the lowermost layer of the component and the carrier substrate 60 is lower than the subsequent adhesive force after melting and bonding of the transfer material. However, care must be taken to ensure that the component is not damaged by this process when it is subsequently lifted off and, in particular, that the individual layers remain undamaged so as not to risk an increased defect density and thus a functional impairment.

The transfer arrangement 1 according to the proposed principle comprises a light generating device 10 for providing a laser pulse with an adjustable strength and an adjustable duration. A plurality of optical fiber lines 20 are connected to the light generating device 10, one of which is shown here as an example. The fiber optic cable 20 has a length and a width “d” which, in the example, is smaller than the corresponding width of the transfer area 41. With an edge length of a μ-LED in the range of 10 μm to 20 μm, the width of the tip of the fiber optic cable can be around 5 μm, for example. This results in certain area ratios. For example, it has proved useful in some applications if the area of the tip of the fiber optic cable or the lifting element is in the range of 20% to 40% of the area of the transfer area. Although a larger area is also possible, it should be ensured that the fiber optic cable does not touch an adjacent component due to a slight positioning error.

The light emitting surface 24 is located on the underside and tip of the fiber optic cable 20. The transfer material 30 is applied to the light emitting surface. The height “h” of the transfer material is selected so that it can melt when a light pulse is applied, but does not change its shape or only changes it insignificantly. In this embodiment example, the contact 40 is designed as a transparent conductive contact made of ITO, i.e. indium tin oxide. The transfer material 30 is again indium, so that both the contact area 40 or the transfer area 41 and the transfer material 30 have the same or similar materials.

FIG. 1b) now shows the first step of the transfer process in more detail. The fiber optic cable 20 is guided with the light emitting surface towards the component so that the transfer material 30 lightly touches the transfer area 41 of the component. During this step, the vertical direction is monitored and controlled via a control circuit of the transfer arrangement 1 (not shown), which determines the height via a suitable feedback loop. For example, the height until the transfer material 30 touches the transfer area 41 can be determined via an interferometric measurement. Alternatively, capacitive or resistive measurements between the transfer material 30 and the transfer area 41 of the component are also possible. In this way, the distance can be determined precisely and excessive lowering and thus damage to the component can be avoided.

After touching the transfer material on the transfer area 41, a laser light pulse is generated by the light generating device 10 and thus energy is supplied to the transfer material in a localized manner. The laser light pulse leads to localized heating and melting of the transfer material 30 in the area of the light emitting surface. The laser light pulse is selected so short that a longer energy transfer and, in particular, heat conduction into the transfer area and the underlying component is avoided as far as possible. The local melting now causes the transfer material 30 to bond with the transfer area 41 on one side and with the light emitting surface of the fiber optic cable 20 on the other side. In other words, the melted transfer material forms a bridge between the tip of the fiber optic cable 20 and the transfer area 41. After the laser light pulse, the melted transfer material immediately solidifies again, creating an intimate connection between the tip of the fiber optic cable 20 and the component 2.

In the next step of the proposed method shown in FIG. 2c), the component 2 is now separated from the support holder 61 by moving the fiber optic cable with the component connected to it upwards. The adhesive force of the transfer material 30 on the transfer area 41 and on the glass fiber cable 20 is greater than the corresponding adhesive force of the support holder 61 on the component.

The transfer process then takes place in sub-FIG. 2d), in which the component is positioned over a further carrier 70 and a contact area 71 arranged on it. After positioning, the component is lowered again until it touches the contact area 71 again with its contact area 52. In addition, it can now be pressed lightly against the contact area 71 by the transfer arrangement so that there is already a slight contact. Contact area 71 can have the same material as contact area 52, but can also be equipped with a solder paste or a similar material. In particular, it can comprise a soft material so that the component 2 is pressed downwards into the contact area 71 by the slight vertical movement and a good connection is therefore already achieved.

In the next step, a further laser light pulse is now generated in the fiber optic cable 20 and the transfer material 30 is melted again. At the same time, as shown in sub-FIG. 2e), the fiber optic cable 20 and optionally the light generating device 10 move upwards so that the fiber optic cable 20 with the transfer material 30 on it is separated from the transfer area 41 and lifted off. The adhesive force between the now melted transfer material 30 and the transfer area 41 is lower than the corresponding adhesive force between the soft contact material 71 and the contact element 52. In this way, the component remains on the contact area 71.

Alternatively, the component can also be aligned slightly above the target position and the laser light pulse then generated. After the melting process, the component then falls easily onto the end carrier and can then be attached. In both variants, this ensures a secure transfer of the component to the target substrate 70 and the contact area 71.

As shown in FIG. 2e), the transfer material 30 remains on the fiber optic cable 20. It must be ensured that the adhesive force of the transfer material 30 in the melted state on the light emitting surface of the fiber optic cable 20 is greater than on the transfer area 41. In this way, the melted transfer material can be detached from the transfer area 41 so that only small residues remain on the transfer area. If the transfer material is used appropriately, these residues are not a problem during further processing of the transfer area 41′ and can even be used for further processing, depending on the transfer material used.

However, it is useful to consume as little transfer material as possible during this process, i.e. to leave it on the surface of the transfer area 41′, in order to enable as many transfer processes as possible with the same glass fiber line and the same transfer material. In this context, it can therefore be advantageous to coordinate the vertical movement and the generation of the light pulse so that the glass fiber line 20 moves upwards at the same time during local melting.

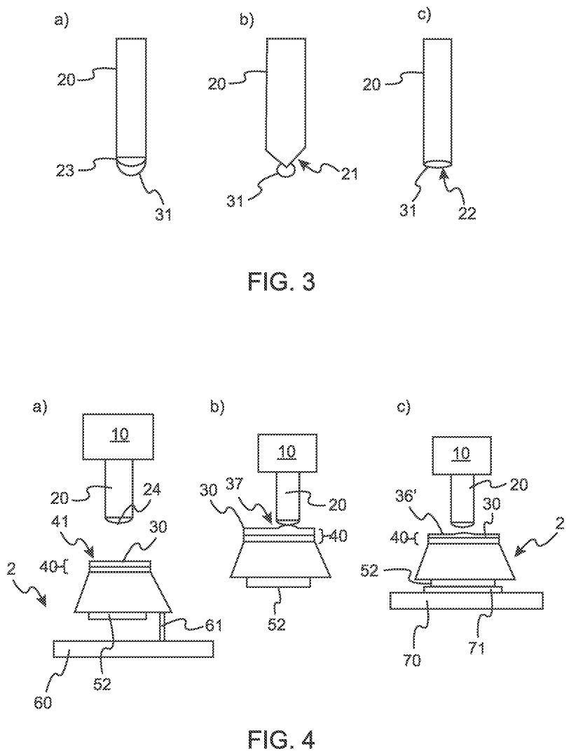

FIG. 3 shows possible designs of the tip of the fiber optic cable 20 for transferring components. In the left-hand part of figure a), the fiber optic cable 20 is formed with a hemispherical tip 23, which has a semicircular cross-section as shown. The transfer material 31 is now applied to this hemispherical tip 23. During melting, the transfer material forms a slight drop shape, so that the height of the transfer material increases slightly as a result of the melting process. As a result, the tip can also be positioned slightly (only a few nm) above the transfer area and does not need to touch it. In an alternative embodiment, the tip can also be moved slightly downwards during the melting process, so that the contact surface of the transfer material with the transfer area is increased and the material essentially fills the space between the hemispherical tip and the transfer area.

In addition to the spherical shape of the tip 23, a lens shape or another design, in particular a different shape of the surface of the tip, is also possible. This allows the light to be focused or de-focused, for example, in order to control the melting process to a certain extent.

In the middle subfigure b), the tip of the glass fiber line is conical so that the melted transfer material 31 collects as a drop on the tip of the glass fiber line. This makes it easier to control the amount of transfer material, and the structure and shape of the drop of transfer material can be changed by the melting process. This embodiment thus makes it possible to position the tip of the fiber optic cable 20 above the transfer area and then melt the transfer material 31 so that it forms a bridge between the tip of the fiber optic cable and the transfer area.

Another embodiment is shown in the right-hand partial figure, in which the end 22 of the fiber optic cable 20 is curved inwards. The transfer material now fills this indentation and forms a flat and smooth surface. In a transfer process with this tip, the fiber optic cable is lowered onto the component and the transfer area 41 and the transfer material is then melted in the recess. This now bonds with the transfer area so that the component can be lifted off after the transfer material has solidified. Such a design of the glass fiber tip can be advantageous if the adhesive forces between the glass fiber tip and transfer material as well as the transfer material and transfer area are roughly balanced. The larger surface area in the glass fiber tip exerts a greater force on the transfer material so that it remains in the tip after a lift-off process.

Depending on the design of the various adhesion forces, the melting process and the process of moving away, different residues can form on the surface of the transfer area. The lifting process can also lead to the transfer material being torn off or cut off, so that a special combination and adjustment of the various parameters is necessary in these areas in particular. On the other hand, the process allows the various parameters to be coordinated with each other.

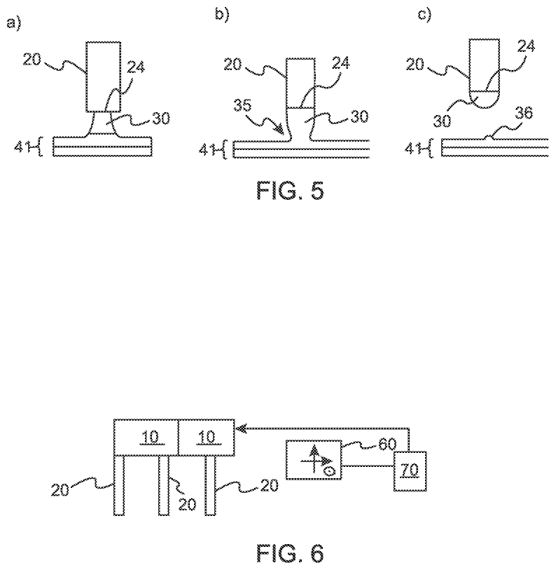

The parameters can include the temperature of the transfer material, the viscosity of the transfer material due to the melting process and the speed of the movement, i.e. the vertical movement during the first melting process and the second melting process. The choice of transfer material and the different surface properties of the transfer area and the light emitting surface can also play a role in this process. Sub-FIGS. 5a) to 5c) show such a lift-off process in its various sub-stages to explain some aspects of the proposed principle.

Partial FIG. 5a) shows a section of a transfer area 41 of a component after it has been transferred and placed on the target substrate. The component is connected to the light emitting surface 24 of the fiber optic cable 20 via a material bridge made of the transfer material 30. As shown in this embodiment example, the adhesive surface of the transfer material 30 on the transfer area 41 and the adhesive surface on the light emitting surface 24 are approximately the same size. After liquefaction of the transfer material 30 by the second melting process, the glass fiber line is now moved away slightly, as shown in sub-FIG. 5b). Due to the higher adhesion forces between the transfer material 30 and the surface of the light emitting surface 24, a large part of the material 30 remains on the glass fiber line, so that a constriction 35 is formed between the surface of the transfer area 41 and the transfer material 30. The constriction is characterized by a smaller amount of material. In a subsequent step, the contact area 71 is soldered or otherwise attached to the contact 52 on the target substrate. This step can also be carried out if the connection between the fiber optic cable 20 and the transfer area 30 still exists and may have the advantage that the component is held in position by the fiber optic cable during the soldering or connection process.

As the distance of the fiber optic cable from the surface of the transfer area 41 increases, the constriction 35 becomes stronger until it finally breaks off and the solidifying drop of transfer material 30 is located on the light emitting surface 24 of the fiber optic cable 20. Only a very small residue 36 of the transfer material remains on the surface of the transfer area 41. This only plays a subordinate role for the further processing of the surface of the transfer area and can also be removed by a corresponding cleaning step.

With a suitable choice of transfer material 30, the residue can also be completely or almost completely avoided. A suitable choice also makes it possible to use the residue in further processing if necessary. For example, it makes sense to use gold or silver as a transfer material if this is also to be used as a material for a contact on the transfer area.

FIGS. 4A to 4C show a further embodiment example of a method for transferring an electronic component according to the proposed principle. In contrast to the preceding embodiment example, in this embodiment the transfer material 30 is not located on the light emitting surface of the optical fiber line 20, but on the electronic component 2 itself. This embodiment has the advantage that the transfer material can already be applied to the transfer area 41 during the manufacture of the component 2, and this is also available for further process steps after a transfer. The component 2 is connected to a carrier 60 via a support holder 61. In this embodiment example, the support holder 61 is arranged decentrally, so that the component is essentially only held on the carrier 60 with the support of the bracket 61. Sacrificial layers between the component 2 and the carrier substrate 60 have been removed.

As in the previous example, the transfer arrangement also comprises a light generating device 10 and a fiber optic cable 20 with a tip connected to it. In the embodiment example, this is elliptical in shape. For the transfer process, the fiber optic cable 20 is moved in the direction of the component and the transfer material arranged on the transfer area until the tip 24 lightly touches it. As in the previous embodiment example, a capacitive measurement or an interferometric measurement can also be used for precise positioning.

Once the fiber optic cable of the tip 24 has been correctly positioned above the transfer material 30, a laser light pulse is generated and emitted via the light emitting surface. At this point, the transfer material 30 melts and is slightly pulled onto the tip of the fiber optic cable 20 by adhesion forces. The laser light pulse is switched off so that the transfer material 30 solidifies and forms the spherical elevation 36 shown in sub-FIG. 4B. The component can then be removed from the support holders 61 and transferred to the target substrate 70. As shown in FIG. 4c), the component is placed on the contact area 71 of the target substrate 70 and pressed lightly into it. A second light pulse is then generated and the transfer material is melted again. During the second melting process and at the time when the transfer material is still liquid, the glass fiber line 20 is moved slightly upwards so that the transfer material flows off the tip 24 of the glass fiber line and remains on the component. Only in the area 36′ can a slight elevation remain in the transfer material after complete cooling. By using an elliptical surface, the transfer material flows back onto the component during the second melting process so that only a small amount of material remains on the surface of the light emitting surface.

The process described here can be applied to a variety of electronic components and can be easily scaled. In this way, a mass transfer of components from a wafer can be carried out. It is also possible to only selectively deposit components on the carrier substrate during the transfer using a second light pulse, so that this process also provides a correction option. For example, components can be selectively moved to positions that are not populated and placed on these by the new laser light pulse.

The fiber optic cables used can be cleaned of excess transfer material using additional light pulses. On the other hand, it is also conceivable to apply a transfer material to the optical fibers again. To do this, the tip of the fiber optic cable is positioned over a material reservoir and material is then melted locally there. And the glass fiber is lowered into the liquid transfer material so that a material remains on the tip and the light emitting surface.

The energy input into the transfer material can be controlled by generating light pulses of different strengths and lengths. It is also conceivable to provide different materials for different components to be transferred so that a high degree of flexibility is achieved overall.

FIG. 6 shows a schematic design of a transfer arrangement. As already shown, the transfer arrangement comprises a plurality of glass fiber lines 20, the distances between which are selected so that they correspond to the distances between the components to be transferred. As shown in the embodiment example, the glass fiber lines can be controlled individually, but also together by light generating devices 10. In this respect, it is therefore possible to selectively pick up and place components. The tips of the fiber optic cables are suitably shaped. In some aspects, the fiber optic cable tips can also be interchanged so that different tips can be transferred depending on the size of the components. In general, the area of the tips of the fiber optic cables is smaller than the area of the transfer area, thus ensuring that the fiber optic cable is still positioned on or above the transfer area even if it is slightly offset and, in particular, does not touch an adjacent component.

The transfer arrangement comprises a movement unit 60, by means of which the individual fiber optic cables can be moved both in their vertical direction and in their horizontal direction. In this respect, the movement unit 60 can comprise stepper motors or piezoelectric elements for vertical and horizontal movement. For appropriate control, a control and monitoring circuit 70 is provided, which is connected both to the movement unit 60 and to the individual light-generating devices 10.

The control and monitoring circuit 70 can comprise several feedback loops and sensor systems to enable precise positioning and alignment. Positioning in the vertical direction can be adjusted in this respect by capacitive, resistive or even interferometric measurements. For this purpose, corresponding support and measuring points for a laser can be provided on the wafer with the components to be transferred and the target wafer. In a capacitance measurement, the wafer and the electronic components located on it can be subjected to a potential either together or individually and the distance between the light emission side and the surface of the component and the transfer area can be determined.

1-25. (canceled)

26. A method for transferring a component, the method comprising:
providing at least one component attached to a first carrier via a support holder, the component having a transfer area on a side facing away from the first carrier;
positioning a light-conducting lifting element with a light emitting surface opposite the transfer area;
generating a first laser light pulse through the light emitting surface;
locally melting a transfer material between the light emitting surface and the transfer area caused by the first laser light pulse;
connecting the light emitting surface to the transfer area with the melted transfer material;
lifting the at least one components so as to separate the component from the support holder;
positioning the at least one component above a deposition area;
generating a second laser light pulse through the light emitting surface so that the transfer material is melted again; and
moving the lifting element away from the transfer area before the transfer material solidifies and so that the component remains on the deposition area.

27. The method according to claim 26, wherein the first and second laser light pulse is generated within the light-conducting lifting element.

28. The method according to claim 26, wherein a duration of the first laser light pulse and/or the second laser light pulse is in a range from 1 ns to 500 ns.

29. The method according to claim 26, wherein positioning comprises:
placing the light-conducting lifting element on the transfer area such that the transfer material touches both the light emitting surface and the transfer area; or
positioning the light-conducting lifting element at a predetermined height above the transfer area such that the transfer material comes into contact with the transfer area during the first laser light pulse due to a change in shape caused by the local melting.

30. The method according to claim 26, wherein the local melting takes place in an area smaller than an area of the light emitting surface.

31. The method according to claim 26, further comprising exerting a force on the transfer area by the light-conducting lifting element while generating the first light pulse.

32. The method according to claim 26, wherein connecting comprises re-solidifying the molten transfer material after generating the first laser light pulse, and wherein an adhesive force to the transfer material on the transfer area and/or to the light emitting surface is greater than a holding force exerted by the support holder to the at least one component.

33. The method according to claim 26, wherein providing the at least one component comprises applying the transfer material to the transfer area.

34. The method according to claim 26, wherein the transfer material comprises a material which is part of a material of the transfer area.

35. The method according to claim 26, wherein the transfer area forms at least part of a contact of the component.

36. The method according to claim 26, wherein less than 20% by mass relative to the original mass of the transfer material, remains on the transfer area after the lifting element has been moved away.

37. The method according to claim 26, further comprising re-melting the transfer material at the light emitting surface by generating a laser light pulse to shape the surface of the transfer material.

38. The method according to claim 26, wherein the transfer material comprises at least one of the following materials: indium, gallium, nickel, silver, gold or tin.

39. The method according to claim 26, wherein the light-conducting lifting element comprises a glass fiber, an end of which forms the light emitting surface.

40. The method according to claim 26, wherein an area of the light emitting surface is in a range of less than 75% of an area of the transfer area.

41. The method according to claim 26, further comprising soldering a second contact to the deposition area, wherein, while soldering, the lifting element remains connected to the transfer area via the transfer material.

42. The method according to claim 26, wherein a tip of the light-conducting lifting element comprises one of the following shapes: a hemispherical tip, a conical tip, a cone-shaped tip, or an inwardly curved recess.

43. A transfer arrangement comprising:
a light generating device configured to generate a first laser light pulse and a second laser light pulse;
a light-conducting lifting element comprising a light emitting surface; and
a movement device which configured to:
move the light emitting surface of the light-conducting lifting element above a transfer area of a component, and
move the lifting element in a vertical direction;
wherein the transfer arrangement is configured to:
connect the component to the lifting element by a transfer material melted by the first laser pulse in the transfer area, and
after a transfer, release the connection through the transfer material again by the second laser pulse.

44. The transfer arrangement according to claim 43, wherein a duration of the first laser light pulse and/or the second laser light pulse is in a range from 1 ns to 500 ns.

45. The transfer arrangement according to claim 43, wherein an area of the light emitting surface is in a range of less than 75% of an area of the transfer area.

46. The transfer arrangement according to claim 43, wherein the transfer arrangement is configured to exert a force on the transfer area during generation of the first light pulse from the light-conducting lifting element.

47. The transfer arrangement according to claim 43, further comprising:
one or more sensors configured to detect a distance between a deposition area and the light emitting surface or values derived therefrom; and
a command and control circuit connected to the one or more sensors and the movement device configured to control vertical movement in response to signals from the one or more sensors.

48. The transfer arrangement according to claim 43, wherein a tip of the light-conducting lifting element comprises one of the following shapes: a hemispherical tip, a conical tip, a con-shaped tip, or an inwardly curved recess.

49. The transfer arrangement according to claim 43, wherein the light emitting surface is covered with the transfer material.

50. The transfer arrangement according to claim 43, further comprising a transfer material reservoir configured to supply the transfer material to the light emitting surface.
